(19) United States
(12) Patent Application Publication
(10) Pub. No.: US 2018/0190792 A1
(43) Pub. Date: Jul. 5, 2018

(54) METHOD OF FORMING SEMICONDUCTOR STRUCTURE AND RESULTING STRUCTURE

(71) Applicant: GLOBALFOUNDRIES INC., Grand Cayman (KY)

(72) Inventors: Jianwei Peng, Latham, NY (US); Hsien-Ching Lo, Clifton Park, NY (US); Suresh K. Regonda, Clifton Park, NY (US); Edward P. Reis, JR., Ballston Spa, NY (US)

(21) Appl. No.: 15/397,967

(22) Filed: Jan. 4, 2017

(51) Int. Cl. H01L 29/66; H01L 21/265; H01L 21/3065; H01L 29/78; H01L 29/08; H01L 29/06

(52) U.S. Cl. CPC H01L 29/66636; H01L 21/26513; H01L 21/3065; H01L 29/0649; H01L 29/7851; H01L 29/0847; H01L 29/66795

(57) ABSTRACT

The disclosure is directed to a semiconductor structure and method of forming same. The method including: implanting a species within a region of a substrate adjacent to a gate stack; forming a first spacer laterally adjacent to the gate stack over the substrate; and forming an opening within the implanted region of the substrate, the opening being substantially U-shaped and self-aligned with the first spacer. The semiconductor structure including: a fin; a gate stack substantially surrounding the fin; a first pair of spacers over the fin and laterally adjacent to the gate stack; and a pair of substantially U-shaped cavities within the fin and on opposing sides of the gate stack, the pair of substantially U-shaped cavities being self-aligned with the first pair of spacers, wherein the pair of substantially U-shaped cavities are filled with a source/drain material.

### BACKGROUND

### Technical Field

The present disclosure relates to semiconductor structures, and more particularly to methods of forming semiconductor structures including a self-aligned U-shaped cavity and resulting structures.

### Related Art

In modern integrated circuits, such as microprocessors, storage devices and the like, a very large number of circuit elements, especially transistors, are provided and operated on a restricted chip area. In integrated circuits fabricated using metal-oxide-semiconductor (MOS) technology, field effect transistors (FETs) (with both n-type MOS (NMOS) and p-type MOS (PMOS) transistors) are provided that are typically operated in a switching mode. That is, these transistor devices exhibit a highly conductive state (on-state) and a high impedance state (off-state). FETs may take a variety of forms and configurations. For example, among other configurations, FETs may be either so-called planar FET devices or three-dimensional (3D) devices, such as finFET devices.

A FET, irrespective of whether an NMOS transistor or a PMOS transistor is considered, and irrespective of whether it is a planar or 3D device, typically comprises doped source/drain regions that are formed in a semiconductor substrate that are separated by a channel region. A gate insulation layer is positioned above the channel region and a conductive gate electrode is positioned above the gate insulation layer. The gate insulation layer and the gate electrode together may sometimes be referred to as the gate stack structure for the device. By applying an appropriate voltage to the gate electrode, the channel region becomes conductive and current is allowed to flow from the source region to the drain region. In a planar FET device, the gate stack is formed above a substantially planar upper surface of the substrate. In a 3D device, the gate stack substantially surrounds a fin.

As integrated circuits continue to scale down, e.g., 7 nanometer and beyond, space on the integrated circuit becomes more valuable and small changes in sizing of structures can greatly impact device performance. Conventional FETs may include a substantially round or ball-shaped cavities on opposing sides of a gate stack in which a source and/or drain may be formed. However, this results in a non-uniform channel length, i.e., the length of the channel between the cavities. This cavity shape limits device performance as a middle portion of the channel region between the two cavities is smaller than at an upper and/or lower portion of the channel region due to the bulbous portion of a ball-shaped cavity defining the channel length in the middle portion. With the scaling down of integrated circuits uniform channel length becomes more important in influencing device performance.

### SUMMARY

A first aspect of the disclosure is directed to a method of forming a semiconductor structure. The method including: implanting a species within a region of a substrate adjacent to a gate stack; forming a first spacer laterally adjacent to the gate stack over the substrate; and forming an opening within the implanted region of the substrate, the opening being substantially U-shaped and self-aligned with the first spacer.

A second aspect of the disclosure is directed to a method of forming a semiconductor structure. The method including: implanting a species within a region of a fin, the fin having a gate stack substantially surrounding the fin and the region of the fin being adjacent to the gate stack; forming a first spacer over at least a portion of the implanted region of the fin and laterally adjacent to the gate stack; and forming an opening within the implanted region of the fin, the opening being substantially U-shaped and self-aligned with the first spacer.

A third aspect of the disclosure is related to a semiconductor structure. The semiconductor structure may include: a fin; a gate stack substantially surrounding the fin; a first pair of spacers over the fin and laterally adjacent to the gate stack; and a pair of substantially U-shaped cavities within the fin and on opposing sides of the gate stack, the pair of substantially U-shaped cavities being self-aligned with the first pair of spacers, wherein the pair of substantially U-shaped cavities are filled with a source/drain material.

The foregoing and other features of the disclosure will be apparent from the following more particular description of embodiments of the disclosure.

### BRIEF DESCRIPTION OF THE DRAWINGS

The embodiments of this disclosure will be described in detail, with reference to the following figures, wherein like designations denote like elements, and wherein:

FIGS. 1-4 show cross-sectional views of a semiconductor structure undergoing aspects of a method according to embodiments of the disclosure, wherein a resulting semiconductor structure is shown in FIG. 4 after sources/drains have been formed.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

The present disclosure relates to semiconductor structures, and more particularly to methods of forming semiconductor structures including a self-aligned U-shaped cavity and resulting structures. Conventional semiconductor structures, e.g., FETs, may include a substantially round or ball-shaped cavities on opposing sides of a gate stack in which a source and/or drain may be formed. However, this results in a non-uniform channel length, i.e., the length of the channel between the cavities. This cavity shape limits device performance as a middle portion of the channel region between the two cavities is smaller than at an upper and/or lower portion of the channel region due to the bulbous portion of a ball-shaped cavity defining the channel length in the middle portion. In contrast to conventional semiconductor structures, the present disclosure includes a semiconductor structure having a substantially uniform channel length as the cavities are substantially U-shaped, and methods of forming the same.

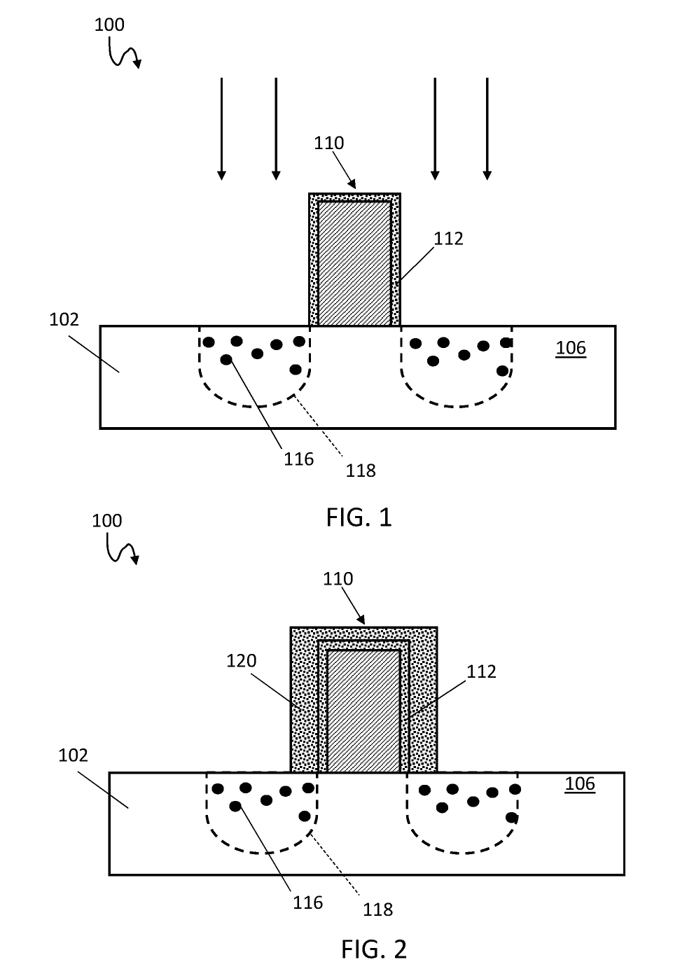

FIG. 1 shows a cross-sectional view of a preliminary semiconductor structure 100 according to embodiments of the disclosure. Semiconductor structure 100 may include a fin-shaped field-effect-transistor (FinFET). However, it is to be understood that embodiments of the disclosure are equally applicable to other types of FETs, e.g., a planar FET. Semiconductor structure 100 may include a substrate 102 from which at least one fin 106 may be formed. Substrate 102 may include but is not limited to silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or entire semiconductor substrate 102 may be strained. While substrate 102 is shown as including a single layer of semiconductor material, it is emphasized that the teachings of the disclosure are equally applicable to semiconductor-on-insulator (SOI) substrates. As known in the art, SOI substrates may include a semiconductor layer on an insulator layer on another semiconductor layer (not shown). The semiconductor layers of an SOI substrate may include any of the semiconductor substrate materials discussed herein. The insulator layer of the SOI substrate may include any now known or later developed SOI substrate insulator such as but not limited to silicon oxide.

One or more (or a set of) semiconductor fins 106 may be patterned, e.g., with a mask in place, and etched from substrate 102. Where substrate 102 includes an SOI substrate, fins 106 may be patterned and etched from the uppermost semiconductor layer. As used herein, “etching” generally refers to the removal of material from a substrate or structures formed on the substrate by wet or dry chemical means. In some instances, it may be desirable to selectively remove material from certain areas of the substrate. In such an instance, a mask may be used to prevent the removal of material from certain areas of the substrate. There are generally two categories of etching, (i) wet etch and (ii) dry etch. Wet etching may be used to selectively dissolve a given material and leave another material relatively intact. Wet etching is typically performed with a solvent, such as an acid. Dry etching may be performed using a plasma which may produce energetic free radicals, or species neutrally charged, that react or impinge at the surface of the wafer. Neutral particles may attack the wafer from all angles, and thus, this process is isotropic. Ion milling, or sputter etching, bombards the wafer with energetic ions of noble gases from a single direction, and thus, this process is highly anisotropic. A reactive-ion etch (RIE) operates under conditions intermediate between sputter etching and plasma etching and may be used to produce deep, narrow features, such as trenches.

A gate stack 110 may be formed such that gate stack 110 substantially surrounds fin 106 and is disposed perpendicular to fin 106 (such that gate stack 110 goes into and out of the page). Gate stack 110 may be formed by deposition and planarization of conventional active gate stack materials such as, high-k layers (i.e., layers including a high dielectric constant), work function metal layers, optional barrier layers, and gate conductor layers, denoted together herein as “gate stack” 110 and shown as a single layer in FIG. 1 for brevity. However, in other embodiments, gate stack 110 may be formed by a “gate last” process wherein gate stack 110 is a replacement gate stack which replaces a dummy gate stack (not shown) after processing of semiconductor structure 100 and removal of the dummy gate stack.

“Depositing,” as used herein, may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation. “Planarization” refers to various processes that make a surface more planar (that is, more flat and/or smooth). Chemical-mechanical-polishing (CMP) is one currently conventional planarization process which planarizes surfaces with a combination of chemical reactions and mechanical forces. CMP uses slurry including abrasive and corrosive chemical components along with a polishing pad and retaining ring, typically of a greater diameter than the wafer. The pad and wafer are pressed together by a dynamic polishing head and held in place by a plastic retaining ring. The dynamic polishing head is rotated with different axes of rotation (that is, not concentric). This removes material and tends to even out any “topography,” making the wafer flat and planar. Other currently conventional planarization techniques may include: (i) oxidation; (ii) chemical etching; (iii) taper control by ion implant damage; (iv) deposition of films of low-melting point glass; (v) resputtering of deposited films to smooth them out; (vi) photosensitive polyimide (PSPI) films; (vii) new resins; (viii) low-viscosity liquid epoxies; (ix) spin-on glass (SOG) materials; and/or (x) sacrificial etch-back.

As known in the art, high-k layer may include but is not limited to: hafnium oxide (HfO₂), or high dielectric constant (>3.9) materials. Work function metal layers may act as a doping source, and a different work function setting metal can then be employed depending on whether a n-type field-effect-transistor (NFET) or a p-type field-effect-transistor (PFET) device is desired. Thus, the same gate conductor can be used in each of the devices, yet a different (if so desired) work function setting metal can be used in one or more devices to obtain a different doping polarity. By way of example only, suitable work function setting metals for use in PFET devices include, but are not limited to aluminum, dysprosium, gadolinium, and ytterbium. Suitable work function setting metals for use in NFET devices include, but are not limited to lanthanum, titanium, and tantalum. Optional barrier layers may include, for example, titanium nitride, tantalum nitride, hafnium nitride, hafnium silicon nitride, titanium silicon nitride, tantalum silicon nitride, tungsten nitrogen carbide, and hafnium aluminum nitride. Gate conductor layers may include, for example, at least one of: titanium, titanium nitride, tungsten, tungsten nitride, copper, copper nitride, tantalum, or tantalum nitride.

Further, a spacer 112 may be formed, e.g., by depositing a spacer material, laterally adjacent to gate stack 110. That is, spacer 112 may be formed on opposing sides of, and in some embodiments over, gate stack 110. Spacer 112 may include any now known or later developed gate spacer material, e.g., silicon nitride. Spacer 112 may substantially surround fin 106 and be disposed perpendicular to fin 106 (such that spacer 112 goes into and out of the page). As shown in FIG. 1, a species 116 may be implanted within a region of substrate 102, or more particularly, fin 106, to form implanted region 118. Species 116 may be implanted within fin 106 adjacent to, and on opposing sides of, gate stack 110. Species 116 may be implanted with a mask in place such that the implanting of species 116 within fin 106 is accomplished at a desired location, e.g., implanted region 118, without implanting species 116 in other, undesirable locations within fin 106. Species 116 may include, for example, at least one of: arsenic or antimony. Species 116 may include any species that can exponentially increase the etch rate of substrate 102 (or fin 106). Species 116 may be implanted by, for example, ion implantation. Species 116 may be implanted at a low dose, e.g., approximately 5E13 ions/cm² to approximately 5E14 ions/cm². Species 116 are implanted with a low energy, typically less than approximately 10 keV in a manner that is self-aligned to spacer 112. Species 116 may be implanted to a depth within substrate 102 or fin 106, for example, of approximately 3 nanometers (nm) to approximately 30 nm depending on desired application.

Turning now to FIG. 2, a spacer 120 may be formed, e.g., by depositing a spacer material, laterally adjacent to gate stack 110 over substrate 102, or more specifically, fin 106. That is, spacer 120 may be formed on opposing sides of, and in some embodiments over, gate stack 110, or more specifically spacer 112. Spacer 120 may be formed such that it substantially surrounds fin 106. Spacer 120 may include any now known or later developed spacer material, e.g., silicon nitride. Spacer 120 may be formed at least partially directly over at least a portion of the implanted region 118 on opposing sides of gate stack 110. As shown, spacer 112 may be disposed substantially between spacer 120 and gate stack 110. Spacer 112 may include a thickness, i.e., lateral width, that is less than a thickness of spacer 120. Spacer 112 may include a thickness, for example, that is less than or equal to approximately 4 nm. That is, in some embodiments, spacer 112 may have a thickness that is 0 nm and thus, may not be included at all. Spacer 120 may include a thickness, for example, that is approximately 2 nm to approximately 20 nm.

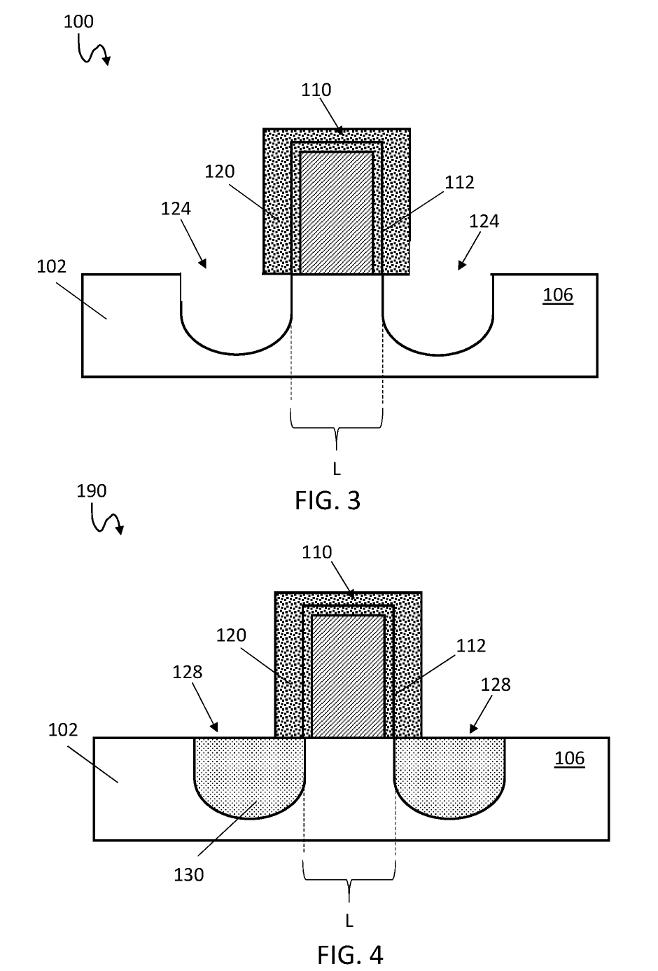

Turning now to FIG. 3, openings 124 may be formed within implanted region 118 (FIG. 2) of substrate 102 or fin 106 on opposing sides of gate stack 110. Openings 124 may be substantially U-shaped and/or include a substantially U-shaped cross-section. As used herein “substantially U-shaped” refers to a shape of openings that resembles a “U” in cross profile and may include a substantially bulbous bottom surface and substantially linear, non-angled sidewalls perpendicular to an upper surface of substrate 102. Openings 124 are self-aligned with the surface between spacer 112 and spacer 120 in a manner that the etching process removes all the implanted silicon of substrate 102 (or fins 106) and limited as the implanted substrate 102 has a significant faster etch rate based on dry etching process than an un-doped substrate. Openings 124 may undercut substrate 102 or fin 106, and openings 124 partially extend beneath spacer 120. Openings 124 may be formed by dry etching, such as for example, RIE or a dry etch using chlorine gas. The etch may be selective to species 116 used such that implanted region 118 (FIG. 2) is selectively removed. A rate of the forming, i.e., etching, of openings 124 is modulated or controlled by species 116 (FIG. 2). That is, the present disclosure provides for the implanting of species 116 to control an etch rate of the etching that is used to form openings 124. In this way, the species 116 enhances the etch rate and the ability to control the etching thereby creating the substantially U-shaped openings 124. Because the implanting of species 116 is done at a low dose, the implanting does not weaken bonds or lattice structure of the material of substrate 102, and thus does not result in defects during the etching of openings 124. The substantially U-shaped openings 124 provide for a substantially uniform channel length L and thus, increase device performance. Channel length L may be approximately 5 nm to approximately 50 nm.

As shown in FIG. 4, a source/drain 128 can be formed in each of openings 124 (FIG. 3). As known in the art, source/drain material 130 may formed, e.g., deposited or epitaxially grown, within openings 124 to substantially fill openings 124. As also known in the art, source/drain 128 may be doped in situ or by ion implantation. Source/drain 128 may be raised source/drains in some embodiments. A resulting semiconductor structure 190, e.g., FINFET, may be formed having substantially uniform channel length L and increased device performance as compared to conventional semiconductor structures.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

1. A method of forming a semiconductor structure, the method comprising:
implanting a species within a region of a substrate adjacent to a gate stack;
forming a first spacer laterally adjacent to the gate stack over the substrate; and
forming an opening within the implanted region of the substrate, the opening having a substantially U-shaped cross-profile including a substantially bulbous bottom surface, wherein the opening is self-aligned with an inner surface of the first spacer, and wherein the forming of the opening is controlled by the implanting of the species.

2. The method of claim 1, wherein the species includes at least one of: arsenic or antimony.

3. The method of claim 1, wherein the forming the opening includes etching the implanted region of the substrate using a dry etch.

4. The method of claim 3, wherein the dry etch includes using a chlorine gas.

5. The method of claim 1, wherein the first spacer is formed at least partially directly over the implanted region of the substrate.

6. The method of claim 1, further comprising:
forming a source/drain material within the opening.

7. The method of claim 1, further comprising:
prior to the implanting, forming a second spacer laterally adjacent to the gate stack, the second spacer being laterally narrower than the first spacer, wherein the opening is self-aligned with an interface between the inner surface of the first spacer and an outer surface of the second spacer.

8. A method of forming a semiconductor structure, the method comprising:
implanting a species within a region of a fin, the fin having a gate stack thereon and the region of the fin being adjacent to the gate stack;
forming a first spacer over at least a portion of the implanted region of the fin and laterally adjacent to the gate stack; and
forming an opening within the implanted region of the fin, the opening having a substantially U-shaped cross-profile including a substantially bulbous bottom surface, wherein the opening is self-aligned with an inner surface of the first spacer, and wherein the forming of the opening is controlled by the implanting of the species.

9. The method of claim 8, wherein the species includes at least one of: arsenic or antimony.

10. The method of claim 8, wherein the forming the opening includes etching the implanted region of the fin using a dry etch.

11. The method of claim 10, wherein the dry etch includes using a chlorine gas.

12. The method of claim 8, wherein at least a part of the first spacer is formed directly over the implanted region of the fin.

13. The method of claim 8, further comprising:
forming a source/drain material within the opening.

14. The method of claim 8, further comprising:
prior to the implanting, forming a second spacer laterally adjacent to the gate stack, the second spacer being laterally narrower than the first spacer, wherein the opening is self-aligned with an interface between the inner surface of the first spacer and an outer surface of the second spacer.

15-20. (canceled)

21. A method of forming a semiconductor structure, the method comprising:
forming a first spacer laterally adjacent to a gate stack over a substrate;
implanting a species within a region of the substrate adjacent to the gate stack;
forming a second spacer laterally adjacent to the first spacer over the substrate; and
forming an opening within the implanted region of the substrate, the opening having a substantially U-shaped cross-profile including a substantially bulbous bottom surface, wherein the opening is self-aligned with the first spacer, and wherein the forming of the opening is controlled by the implanting of the species.

22. The method of claim 21, wherein the species includes at least one of: arsenic or antimony.

23. The method of claim 21, wherein the forming the opening includes etching the implanted region of the substrate using a dry etch.

24. The method of claim 23, wherein the dry etch includes using a chlorine gas.

25. The method of claim 21, wherein at least a portion the second spacer is formed directly over the implanted region of the substrate, and wherein the first spacer is laterally narrower than the first spacer.

26. The method of claim 21, further comprising:
forming a source/drain material within the opening.
